(19) United States
(12) Patent Application Publication
(10) Pub. No.: US 2009/0109619 A1
(43) Pub. Date: Apr. 30, 2009

(54) METHOD APPARATUS FOR COOLING SYSTEM HAVING AN S-SHAPED AIR FLOW PATH FOR USE IN A CHASSIS

(75) Inventors: Jeffrey L. Wise, Acton, MA (US); David S. Chau, Chandler, AZ (US); Stephen A. Hauser, Carlisle, MA (US); Pasi J. Vaananen, Waltham, MA (US)

Correspondence Address: MOTOROLA, INC., 1303 EAST ALGONQUIN ROAD, IL01/3RD, SCHAUMBURG, IL, 60196, US

(73) Assignee: MOTOROLA, INC., Schaumburg, IL (US)

(21) Appl. No.: 11/924,217

(22) Filed: Oct. 25, 2007

(51) Int. Cl. H05K 7/20

(52) U.S. Cl. 361/695

(57) ABSTRACT

A method and apparatus cooling a chassis. The apparatus includes a telecommunication shelf structure or chassis (102) having a top side (108), bottom side (110), front side (104) and back side (108). Slots that can support boards (112) are oriented between the top side and the bottom side. A first set of fans (126) pushes air flow through the slots from the front and bottom sides of the shelf structure to the top and back sides of the shelf structure, and a second set of fans (128) pulls air flow through the slots from the front and bottom sides of the shelf structure to the top and back of the shelf structure. The first and second set of fans form a fault tolerant and redundant fan configuration in the telecommunication shelf structure to achieve an S-shaped air flow through the telecommunication shelf structure.

### FIELD OF THE INVENTION

The present invention relates generally to cooling systems and, in particular, for cooling systems that have an S-Shaped air flow path through a chassis that is used in telecommunication computer systems.

### BACKGROUND

Embedded computer chassis systems generally include numerous chassis-mounted computer cards connected to a backplane or a midplane. The computer cards may include payload cards and switch cards that communicate using a bus or a switch fabric topology over the backplane or midplane. The payload cards and switch cards may be chosen as to provide the chassis with the functionality and features desired by a user.

Each embedded computer chassis system generally includes cooling fans mounted in the chassis to cool the computer cards. Periodically these cooling fans need to be removed for maintenance and replacement. For each region in an embedded computer chassis, monolithic fan trays that contain a number of cooling fans are used. It is known that there can be redundancy in the number of fans in the fan tray.

As telecommunication systems and the mounted computer cards advance and become more complex, the environmental conditions within the chassis that support the telecommunication hardware become more severe. The chassis are required to support the combination of high power dissipation from the boards that operate in the chassis with high airflow resistance through the chassis. This combination requires a powerful air cooling architecture that utilizes cooling fans in cooling fan trays. Air cooling systems that are known are not able to provide sufficient cooling to meet specifications as required by standards such as those set by Advanced Telecom Computing Architecture (ACTA).

Computing boards are using different materials that increase the heat generated during operations of the board. In addition, heat in a chassis is increased by the high power boards or blades that are inserted into the chassis that have increased functionality.

ATCA standards require certain airflow through the chassis. The airflow begins in the front of the chassis shelf, and moves across the boards from the bottom to the top of the boards and exits the chassis out of the rear of the shelf. This pattern creates a general S-shaped airflow path through the chassis or shelf.

As the temperature increases in the chassis, there is a need to improve the airflow through the chassis. In particular, there is a need to improve the S-shaped airflow path that is required through the chassis.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is side elevation of an embedded computer chassis made in accordance with some embodiments of the invention.

FIG. 2 is a front elevation of an embedded computer chassis made in accordance with some embodiments of the invention.

FIG. 3 is a rear elevation of an embedded computer chassis made in accordance with some embodiments of the invention.

FIG. 4 is a flow chart diagram of a method of operating fans for the embedded computer chassis made in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to a cooling system having an S-shaped air flow pattern through a chassis. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of a cooling system having an S-shaped air flow pattern through a chassis. The non-processor circuits may include, but are not limited to, a radio receiver, a radio transmitter, signal drivers, clock circuits, power source circuits, and user input devices. As such, these functions may be interpreted as steps of a method to perform cooling of a chassis using an air flow having an S-shaped pattern. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The present invention is directed to an apparatus and system for cooling that has an S-shaped airflow pattern through a chassis. The apparatus includes a telecommunication equipment shelf structure or chassis having a top side, bottom side, front side and back side. Slots are vertically oriented between the top side and the bottom side. A plurality of inlet fans are provided at the front side the shelf structure or chassis, and a plurality of outlet fans are provide at the back side of the shelf structure. The plurality of inlet fans push the air flow through the slots from the front and bottom sides of the shelf structure to the top and back sides of the shelf structure. The inlet fans are positioned at the bottom front side of the shelf structure and can be at a 30° angle from the bottom side to reduce the pressure change between the bottom side and top side of the shelf structure. The plurality of exhaust fans pull the air flow through the slots from the front and bottom sides of the shelf structure to the top and back sides of the shelf structure and are positioned at the top back side of the shelf structure. A first set of vanes can be provided and are oriented along the bottom side of the shelf structure to direct the air towards the top of the shelf structure. A second set of vanes can also be provided and are oriented along the top side of the shelf structure to direct the air towards the exhaust fans. The first and second set of fans form a fault tolerant and redundant fan configuration in the telecommunication shelf structure to achieve the S-shaped air flow through the telecommunication shelf structure. Moreover, the inlet and exhaust fans operate at reduced power when the plurality of inlet and exhaust fans are operational, and at least one of the plurality of inlet and exhaust fans operate at full power when at least one of plurality of inlet and exhaust fans are non-operational to maintain the S-shaped air flow through the telecommunication shelf structure.

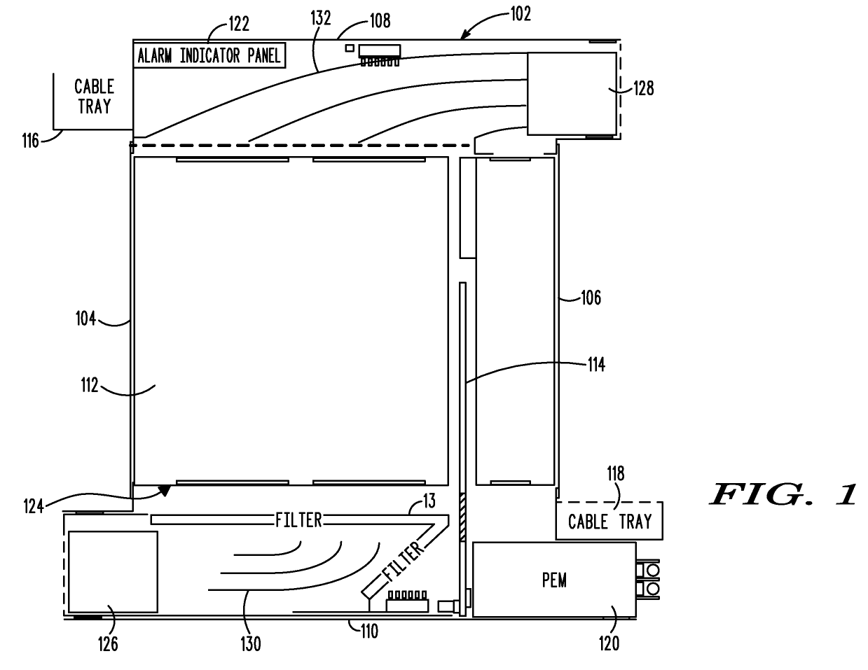

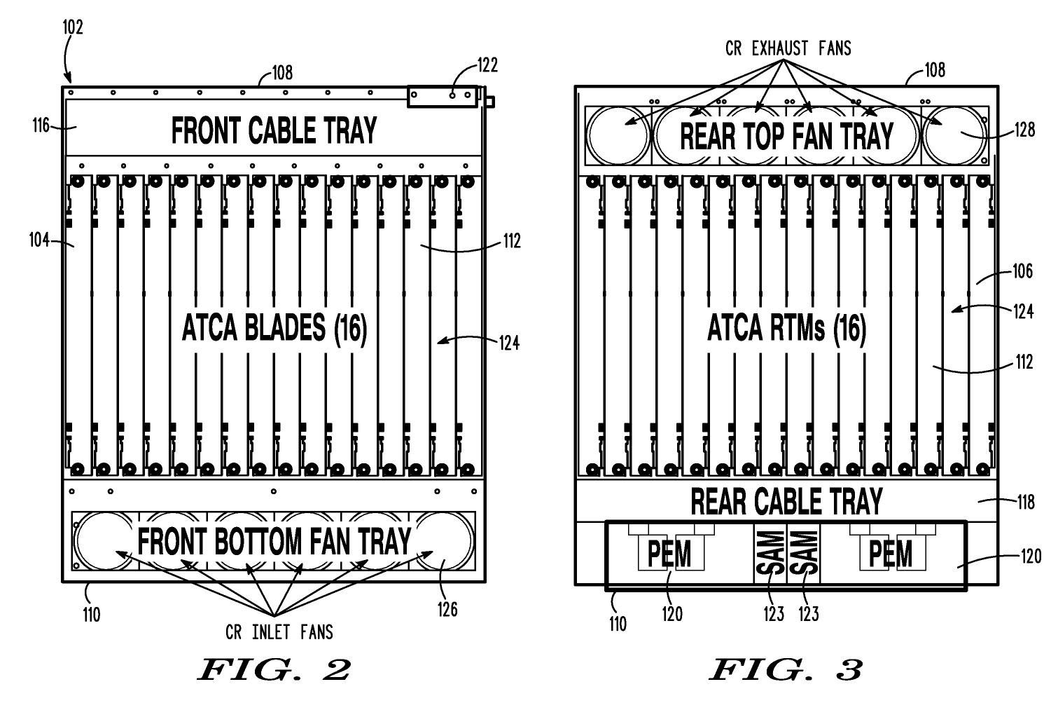

Turning to the Figures, FIG. 1 representatively illustrates a side elevation view of an embedded computer chassis 102 in accordance with the principles of the present invention. FIG. 2 represents a front view of the chassis 102, and FIG. 3 represents the rear view of the same chassis. As shown in the FIGs., embedded computer chassis 102 can be defined by a plurality of outer surfaces included a front side 104 a back side 106, a top side 108 and a bottom side 110. Chassis 102 can include a portion having any number of slots vertically oriented between the top and bottom sides 108, 110 and suitably adapted for receiving one or more computer boards 112. In an embodiment, board 112 can be coupled to a backplane 114. In another embodiment, a front board can be couple to one side of a midplane (not shown) and a rear board can be couple to the other side of the midplane.

Backplane 114 may include hardware and software necessary to implement a data network using a parallel multi-drop topology, switched fabric topology or other known or developed topologies. Backplane 114 is disposed substantially vertically within the chassis 102 and substantially perpendicular to the front side 104 and back side 106 of the chassis.

In addition, chassis 102 includes a front cable tray 116 for cables to connect to boards 112 so that other devices (not shown) can connect to the boards 112. A back cable tray 118 is for cables to connect to the back side of backplane 112. In an alternate embodiment, back cable tray is for cables to connect to the rear boards that are connected to the midplane. Chassis 102 is also provided with at least one power entry module (PEM) 120 positioned at the back and bottom sides of the chassis. PEM 120 provides power management services for the chassis. An alarm indicator panel 122 can also be provided. In addition, shelf manager modules 123 can be provided between the PEMs 120 on the bottom and rear sides of the chassis 102. The operations and functions of PEM 120, alarm indicator panel 122 and shelf manager modules 123 are readily understood by those of ordinary skill in the art of embedded computer chassis.

The computer boards 112 include a printed circuit board (PCB) having any number of electronic devices located on the PCG. For example, and without limitation, processors, memory, storage devices, I/O elements and other hardware components can be disposed on the board 112. The hardware components on the board can include silicon or other known and developed materials.

Embedded computer chassis 102 may be adapted for use in any application requiring modular, embedded computing resources include telecommunications, industrial control, system control and data acquisition (SCADA.) In an embodiment the chassis 102 can be a 1U, 3U, 6U or 9U dimensional chassis. Chassis 102 may be coupled together and “stacked” to form a distributed computing system coupled to share resources from each other. As is known, “U” and multiples of “U” can refer to both the width of a board and the height of the embedded computer chassis 102. In an embodiment, “U” can measure approximately 1.75 inches. As an example of an embodiment, a board portion can be coupled to accommodate 6U form factor boards 112. Any size chassis or board is within the scope of the invention, however. The “U” terminology is not limiting of the invention. As such, the invention is not limited to “U” as a form factor reference. Other form factor reference notations and increments are within the scope of this invention.

In an embodiment, embedded computer chassis 102 may include backplane 114 or the midplane, boards 112 suitably adapted to operate a parallel multi-drop network, for example a VERSEmodule Eurocard (VMEbus) network using any of the VMEbus protocols known in the art. VMEbus is defined in the ANSI/VITA 1-1994 and ANSI/VITA 1.1-1997 standards promulgated by the VMEbus International Trade Association (VITA), P.O. Box 19658, Fountain Hills, Ariz. 85269 (where ANSI stands for America National Standards Institute.) In an embodiment of the invention, VMEbus based protocols can include, but are not limited to, Single Cycle Transfer protocol (SCT,) Block Transfer protocol (BLT,) Multiplexed Block Transfer protocol (MBLT,), Two Edge VMEbus protocol (2eVME) and Two Edge Source Synchronous Transfer protocol (2eSST.) These VMEbus protocols are known in the art.

In another embodiment, chassis 102 may include backplane 112 or a midplane and boards 112 suitably adapted to operate a switch fabric. Switched fabric may use switch boards as a central switching hub with any number of payload boards coupled to the switch board. Switched fabric can be based on a point-to-point, switched input/output (I/O) fabric, whereby cascaded switch devices interconnect end node devices. In an embodiment, switched fabric can be configured as a star topology, mesh topology or other known methods for communicatively coupling switched fabrics. Switched fabric can include both board-to-board (for example computer systems that support I/O board add-in slots) and chassis-to-chassis environments (for example interconnecting computer, external storage systems, external Local Area Network (LAN) and Wide Area Network (WAN) access devices in a data-center environment.) Switched fabric can be implemented by using one or more of a plurality of switched fabric network standards, for example and without limitation, InfiniBand™, Serial RapidIO™, FibreChannel™, Ethernet™, PCI Express™, AdvancedTCA™, Hyperstransport™, Gigabit Ethernet and other known and developed standards. Switched fabric is not limited to the use of these switched fabric network standards and the use of the any switched fabric network standard is in the scope of the invention.

In another embodiment, chassis 102 may include backplane 114 or a midplane and boards 112 suitably adapted to comply with Advanced Telecom and Computing Architecture (ATCA™) standard as defined in the PICMIG 3.0 AdvancedTCA specification. In yet another embodiment, chassis 102 may include backplane 114 and boards 112 suitable adapted to comply with CompactPCI® standard or MicroTCA standard as defined by PICMG® MicroTCA. In still another embodiment, the chassis 102, backplane 114 an boards 112 are suitably adapted to operate a VXS network that conforms to VERSAmodule Eurocard (VMEbus) switched serial standard backplane (VXS) as set forth in VITA 41 promulgated by VITA. VXS network includes a switched fabric and a VMEbus network, both located on a midplane. In other words. A VXS network includes a switched fabric coincident and operation concurrently with a VMEbus network. The embodiment of the invention is not limited to a computer system complying with any of these standards, and computer systems complying with other standards are within the scope of the invention

When in operation, computing cards 112, among other devices, may generate heat that must be removed from the chassis 102. In an embodiment, chassis 102 may include any number of surfaces that need to be cooled whereby the area needing to be cooled is defined as a cooling region 124. Cooling region 124 may include an air plenum region and an interspace region, where the interspace region is suitably adapted to receive the first set of plurality of fans 126 and a second set of plurality of fans 128. The first set of fans 126 may be suitably adapted to be positioned on the bottom side 110. The second set of fans 128 may be suitably adapted to be positioned near the top side 108. In an embodiment, the first set of fans 126 and the second set of fans 128 are substantially redundant and fault tolerant for removing the heat generated within the chassis 102. By substantially redundant and fault tolerant, the use of either the first set of fans 126 or the second sent of fans operating by itself is sufficient to cool the chassis 102 and the cards 112 operating within the chassis.

Cooling region 124 may extend either fully or partially the height of the chassis 102. The specific size and configuration of the cooling region 124 can be tailored to fit a specific application and be within the scope of the invention. Cooling region 124 may include a region around one or more boards 112 and may be suitably adapted to cool the boards 112. A surface of the embedded computer chassis 102, for example front side 104 may include one or more orifices (not shown) to allow cooling air to be drawn into the chassis 102 in a direction substantially perpendicular to front side 104 and back side 106 and into a plenum region at the bottom side 108 of the chassis. Air plenum regions may include an inlet or exhaust screen/filter and a cavity where cooling air enters and exits chassis 102. Cooling air may function to cool heat generating electronics associated with boards 112 and backplane 114. Cooling air may follow a substantially defined path through the chassis 102 and cooling region 124. In an embodiment, the defined path is a generally S-shaped path form the inlet first set of plurality fans 126 through the boards 112 in the cooling region 124 to the exhaust second set of plurality fans 128. This S-shaped path will be defined in more detail below.

First and second set of fans 126, 128 can be of any arrangement suitable to push and pull air through the chassis 102, boards 112 and air cooling region 124 in the desired S-shaped pattern. In an embodiment, the fans 126, 128 are dual-stage counter-rotating fans such that each set includes at six 80×80 mm fans. Alternatively, fans 126, 128 can be any sort of suitable fan including axial fans and radial fans. As is known, each dual-stage counter-rotating fan includes two sets of fan blades that turn in opposite directions to one another. The use of these plurality dual-stage counter-rotating fans 126, 128 at the front and bottom of the chassis as well as the top and back of the chassis creates the desired S-shaped air flow path through the chassis 102, boards 112 and cooling region 124. In addition, the fans 126, 128 configured in this arrangement provides for a redundant cooling arrangement where when one of the plurality of fans in the first and second set needs to be replaced or maintained that the cooling operations of the fan configuration can be continued while the fan is non-operational. In other words, the first set of fans 126 is sufficient by itself to push the air through the chassis in the S-shaped patter to cool the chassis, and the second set of fans 128 is sufficient by itself to pull the air through the chassis in the S-shaped patter to cool the chassis.

In an embodiment, the first set of fans 126 is arranged at an angle directed to the top side 108 of the chassis 102. The angle can be any acute angle in the range of 30°. The angle of the first set of fans 126 initializes the air flow through the chassis 102, boards 112 and cooling region 124 in the S-shaped flow that provides optimal cooling of the chassis 102 and the components within the chassis. The angle of the inlet fans 126 also reduces the pressure of the air at the bottom side of the chassis to aid in the pressure drop between the bottom and top of the chassis. In addition, chassis 102 includes a first set of airflow vanes 130 that are in an interspace cooling region near the bottom side 110 of the chassis. A second set of airflow vanes 132 can be configured in an interspace cooling region near the top side 108 of the chassis 102. In an embodiment, the vanes 130,132 are shaped in such a way to direct the air flow in the desired S-shaped pattern. These airflow vanes 130, 132 also contribute to the S-shaped air flow through the chassis 102, boards 112 and cooling region 124. In an embodiment, filters 134 are provided in the bottom region of the chassis.

In view of the foregoing, an S-shaped air flow pattern through the chassis 102. The air flow begins by the first set of fans 126 acting as inlet fans pushes air into the chassis 102 and the interspace region of the cooling region 124. The dual-stage counter-revolution fans 126 are pointed at a 30° angle initializes the air flow into the first set of vanes 130. Vanes 130 are positioned and arc-shaped to direct the air flow away from striking the back side of the 106 of the chassis and towards the plenum area of the cooling region 124 and the boards 112 positioned in the chassis. As shown in FIG. 1, a filter 134 or other suitable material can be position in the interspace area of cooling region 124 to assist in directing the air flow away from the back side 106 towards the top side 104 of the chassis and through the boards 112.

The S-shaped pattern continues as the air flow exits the first set of vanes and enters the plenum area of the cooling region 124 containing the boards 112. The air flow flows up through the boards to the second set of vanes 132 in the interspace region of the cooling region towards the top side 108 of the chassis. Vanes 132 are also generally arc-shaped to direct the air flow through the interspace region towards the back side 106 of the chassis 102. The air is being pulled along the S-shaped air flow from the boards through the second set of vanes by the second set of fans 128. Second set of fans serve as exhaust fans for the chassis 102, and the air exits the chassis through those fans. The arrangement of the fans 125, 128, vanes 130, 132, filters 134, boards 112 and chassis 102 provide a wind-tunnel design that minimizes obstructions for the air flow through the chassis by creating and aiding the S-shaped airflow through the chassis. Prior art arrangements of fans positioned in the chassis caused inlet fans to push air into the interspace region of the cooling region towards the chassis' back side 106. When the air hit the back side 106 of the chassis 102 the air is deflected towards the top side 108 of the chassis 102. As is understood by present description, however, the S-shaped air flow by the present invention is formed when the air enters the chassis by the vanes 130 and continues on the S-shaped path through the boards and the vanes 132 to the exhaust fans.

In addition to the physical arrangement of the vanes, boards and chassis, the S-shaped air flow pattern is assisted by the arrangement of fans. The dual-stage counter-revolution fans in first and second set of fans 126, 128 create a pressure difference between the bottom side 110 and top side 108 such that the pressure drop between the bottom and top side causes the air flow to rise towards to the top through the vanes and the boards. In addition, the combination of the first set of fans 126 pushing air into the chassis and the cooling region 124 and the second set of fans 128 pulling air out of the chassis 102 and the cooling region also assists in forming the S-shaped air flow pattern.

First and second set of fans 126, 128 are powered by the PEM 120 and managed by the shelf manager 123. PEM 120 and shelf manager 123 can be configured to provide different power levels to the first and second set of fans. The combination of the first set of fans pushing air and the second set of fans pulling air through the chassis, boards and cooling region can reduce the power supplied to the fans necessary to adequately cool the components in the chassis 102. In an embodiment, the configuration of the fans 126, 128 and vanes 130, 132 can reduce the power necessary to effectively cool the chassis by approximately 50 percent. By reducing the power, the fans operate at slower speeds, which reduces noise and maintenance requirements.

In an embodiment, the chassis 102 can be configured with sensors (not shown) that measure the parameters within the chassis and the operations of the fans 126, 128. Thus, the shelf manager knows the temperature within the chassis as well as which fans and fan sets are operational or non-operational. The PEM 120 and shelf manager 123 can be configured to power the fans such the first set of fans can push enough air through the desired S-shape air flow to adequately cool the chassis and the operating components or for the second set of fans to pull enough air through the desired S-shaped air flow. The PEM 120 and shelf manager 123 can provide full power to either the first set of fans or the second set of fans when the other set is non-operational. The combination of the fully powered dual-stage counter-rotating fans with the vanes and boards creating an unobstructed S-shaped air flow though the chassis and the cooling region provides the necessary cooling. In addition, the combination provides an even distribution of airflow between slots and boards and between the front and rear of the boards. In an embodiment, there is a control distribution between the front boards and the rear boards such that a balanced airflow is created. Moreover, reducing the power provided to the first and second set of fans when both sets are operational also provides the necessary cooling based on the combination of a pushing and pulling of air through the vanes, the cooling region and the boards.

In view of the foregoing, the combination of components in the chassis creates a fault tolerant and redundant fan configuration for the chassis. Thus, when an individual fan or a set of fans is removed from service for maintenance or failure, the power of the remaining fans can be appropriately adjusted to compensate for the non-operational fan or set of fans. The adjustment of the power and the formation of the S-shaped air flow provide the necessary cooling. As mentioned in one scenario, a set of fans 125, 128 can be non-operational and the power to the other set of fans can be adjusted to full power level to appropriately push or pull the air flow through the S-shaped air flow path to cool the chassis.

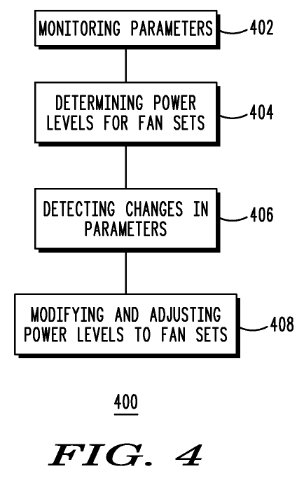

Turning to FIG. 4, a flow chart 400 showing how the power provided to the chassis can be adjusted to the first and second set of fans. As stated, each set of fans includes a plurality of dual-stage counter-rotating fans that each operate independently of one another. Each fan is connected to the PEM 120 and the shelf manager 123. In addition, chassis 102 includes sensors that monitor various parameters and conditions within the chassis. The method begins by monitoring 402 the various parameters including, but not limited to, the overall temperature of the chassis and the status of each fan and set of fans. Based on the parameters, appropriate power levels for each of the fans and set of fans is determined 404. When changes are detected 406 by the sensors, modifications and adjustments 408 can be made to the relevant power levels supplied to the fans and the set of fans. In an embodiment, full power is supplied to one of the set of fans when the other set of fans is non-operational and when at least one fan in each of the fan sets is operational, the fans can be powered at a reduced power level.

In an embodiment, the backplane 114 can be configured with holes (not shown) through the boards. The holes are placed to assist in the equalization, e.g. the slot-to-slot distribution of the air flow as the air travels from the front to the rear of the boards. The holes are therefore aligned towards the rear of the boards and the size achieves the proper flow through the chassis. In addition, open area apertures can be used on the end slots to create additional pressure equalizations among the slots.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

We claim:

1. An apparatus comprising:
a telecommunication shelf structure having a top side, bottom side, front side and back side;
slots oriented between the top side and the bottom side;
a first set of fans for pushing air flow through the slots from the front and bottom sides of the shelf structure to the top and back sides of the shelf structure, and
a second set of fans for pulling air flow through the slots from the front and bottom sides of the shelf structure to the top and back of the shelf structure, and
wherein the first and second set of fans form a fault tolerant and redundant fan configuration in the telecommunication shelf structure to achieve an S-shaped air flow through the telecommunication shelf structure.

2. The apparatus according to claim 1 wherein the first set of fans is angled towards the top side of the shelf structure to reduce turning angles of the air flow through the shelf structure.

3. The apparatus according to claim 2 wherein the angle of the first set of fans is about 30° from the bottom side of the shelf structure.

4. The apparatus according to claim 1 further comprising a first set vanes positioned along the bottom side of the shelf structure wherein the first set of vanes direct the air flow away from the back side towards the top side of the shelf structure to achieve the S-shaped air flow through the telecommunication shelf structure.

5. The apparatus according to claim 4 further comprising a second set of vanes positioned along the top side of the shelf structure wherein the second set of vanes direct the air flow towards the second set of fans to maintain the S-shaped air flow through the telecommunication shelf structure.

6. The apparatus according to claim 1 wherein the first set and second set of fans are two stage counter-directional fans.

7. The apparatus according to claim 1 wherein the first and second set of fans operate at reduced power when both the first and second set of fans are operational and wherein one of the first and second set of fans operate at full power when the other of the first and second set of fans are non-operational.

8. The apparatus according to claim 1 wherein the first set of fans maintains the S-shaped air flow through the telecommunication shelf structure when the second set of fans is non-operational and the second set of fans maintains the S-shaped air flow through the telecommunication shelf structure when the first set of fans is non-operational.

9. The apparatus of claim 1 wherein the first set of fans and the second set of fans provide an even flow distribution between the bottom side of the top side of the shelf structure.

10. The apparatus of claim 1 wherein the first set of fans and the second set of fans provide for a balanced air flow between a front side of boards oriented vertically in the slots and a back side of the boards.

11. An apparatus comprising:
a telecommunication shelf structure having a top side, bottom side, front side and back side;
slots oriented between the top side and the bottom side;
a set of inlet fans creating air flow through the slots from the front and bottom sides of the shelf structure to the top and back sides of the shelf structure and wherein the first set of fans are angled towards the top side of the shelf structure, and
a set of exhaust fans creating air flow through the slots from the top and back sides of the shelf structure to the front and bottom sides of the shelf structure, and
wherein the first and second set of fans form a fault tolerant and redundant fan configuration in the telecommunication shelf structure to achieve an S-shaped air flow through the telecommunication shelf structure.

12. The apparatus according to claim 11 wherein the angle of the inlet fans is 30° from the bottom side of the shelf structure.

13. The apparatus according to claim 11 further comprising a first set of vanes positioned along the bottom side of the shelf structure wherein the first set vanes direct the air flow away from the back side towards the top side of the shelf structure to achieve the S-shaped air flow through the telecommunication shelf structure.

14. The apparatus according to claim 13 further comprising a second set of vanes positioned along the top side of the shelf structure wherein the second set of vanes maintain the S-shaped air flow through the telecommunication shelf structure.

15. The apparatus according to claim 11 wherein the first set and second set of fans are two stage counter-directional fans.

16. The apparatus according to claim 11 wherein the inlet and exhaust fans operate at reduced power when both the inlet and exhaust fans are operational and wherein one of the inlet and exhaust fans operate at full power when the other of the inlet and exhaust fans are non-operational.

17. The apparatus according to claim 11 wherein the inlet fans maintain the S-shaped air flow through the telecommunication shelf structure when the exhaust fans are non-operational and the exhaust fans maintain the S-shaped air flow through the telecommunication shelf structure when the inlet fans are non-operational.

18. The apparatus of claim 11 wherein the inlet and exhaust fans provide an even flow distribution between the bottom side of the top side of the shelf structure.

19. The apparatus of claim 11 wherein the inlet and exhaust fans provide for a balanced air flow between a front side of boards oriented vertically in the slots and a back side of the boards.

20. An apparatus comprising:
a telecommunication shelf structure having a top side, bottom side, front side and back side;
slots oriented between the top side and the bottom side;
a plurality of inlet fans for pushing air flow through the slots from the front and bottom sides of the shelf structure to the top and back sides of the shelf structure wherein the inlet fans are positioned at the bottom front side of the shelf structure at a 30° angle from the bottom side to reduce the pressure change between the bottom side and top side of the shelf structure;
a plurality of exhaust fans for pulling air flow through the slots from the front and bottom sides of the shelf structure to the top and back sides of the shelf structure wherein the exhaust fans are positioned at the top back side of the shelf structure;
a first set of vanes oriented along the bottom side of the shelf structure to direct the air towards the top of the shelf structure, and
a second set of vanes oriented along the top side of the shelf structure to direct the air towards the exhaust fans, and
wherein the first and second set of fans form a fault tolerant and redundant fan configuration in the telecommunication shelf structure to achieve an S-shaped air flow through the telecommunication shelf structure and
wherein the inlet and exhaust fans operate at reduced power when the plurality of inlet and exhaust fans are operational and wherein at least one of the plurality of inlet and exhaust fans operate at full power when at least one of plurality of inlet and exhaust fans are non-operational and maintain the S-shaped air flow through the telecommunication shelf structure.
